(19) United States
(12) Patent Application Publication
(10) Pub. No.: US 2014/0218009 A1
(43) Pub. Date: Aug. 7, 2014

(54) DEVICE FOR MEASURING A DURATION OF A LEVEL OF AN ELECTRICAL SIGNAL

(71) Applicants: David Canard, Colombelles (FR); Matthieu Lecuyer, Colombelles (FR)

(72) Inventors: David Canard, Colombelles (FR); Matthieu Lecuyer, Colombelles (FR)

(73) Assignee: ASAHI KASEI MICRODEVICES CORPORATION, Tokyo (JP)

(21) Appl. No.: 14/241,186

(22) PCT Filed: Aug. 29, 2011
(86) PCT No.: PCT/FR2011/051978

§ 371 Date: Feb. 26, 2014

(51) Int. Cl. G01R 22/00

(52) U.S. Cl. CPC G01R 22/00
USPC 324/76.39

(57) ABSTRACT

A device for measuring a duration of a level of an electrical signal, comprising first ring oscillator comprising inverting gates, whose electrical power supply is modulated by the electrical signal; second ring oscillator whose electrical power supply is not modulated by the electrical signal; first counting unit configured to count a total number of gate-to-gate transitions of a point of instability of the first ring oscillator, a point of instability being present at an inverting gate when a logic level at an input to the inverting gate is equal to a logic level at an output from the inverting gate; second counting unit configured to count a total number of gate-to-gate transitions of a point of instability of the second ring oscillator; and determining unit configured to determine a duration of a level of the electrical signal on a basis of values of the first and second counting units.

This application claims the priority and benefit of PCT patent application no. PCT/FR11/051978 to Asahi Kasei Microdevices Corporation of Japan, entitled “Device For Measuring A Duration Of A Level Of An Electrical Signal,” filed Aug. 29, 2011, which is hereby incorporated by reference in its entirety.

### TECHNICAL FIELD

The invention relates generally to a device for measuring a duration of a level of an electrical signal.

### BACKGROUND

Measuring a duration of an electrical signal is an important operation in many fields, such as metrology, and telecommunications. A conventional solution for making such a measurement is to count the number of pulses generated by an oscillator for the duration of the electrical signal to be measured.

There are various techniques for implementing an oscillator, and all offer advantages and disadvantages. For example, ring oscillators are very attractive for implementation in integrated circuit form, but their characteristics are very sensitive to variations in power supply voltage. If a ring oscillator is to be used, it is then essential to supply a voltage that is as stable as possible and is free of noise. Accordingly, these requirements limit the conditions where such oscillators can be used.

The present invention solves the disadvantages of the prior art by disclosing a device for measuring a duration of a level of an electrical signal that is not sensitive to noise in its electrical power supply nor to any variations in the power supply voltage.

### BRIEF SUMMARY

To achieve these and other objects of the invention, in some embodiments a device for measuring a duration of a level of an electrical signal, comprises a first ring oscillator comprising inverting gates and supplied by an electrical power supply modulated by the electrical signal; a second ring oscillator supplied by an electrical power supply not modulated by the electrical signal; a first counting unit configured to count a total number of gate-to-gate transitions of a point of instability of the first ring oscillator, a point of instability being present at an inverting gate when a logic level at an input to the inverting gate is equal to a logic level at an output from the inverting gate; a second counting unit configured to count a total number of gate-to-gate transitions of a point of instability of the second ring oscillator; and a determining unit configured to determine a duration of a level of the electrical signal on a basis of values of the first and second counting units.

Therefore, the count of the transitions of the modulated first oscillator, representing the duration of the level of the electrical signal, can be corrected by counting the transitions of the unmodulated second oscillator. Errors related to fluctuations in the power supply voltage, such as those due to noise in the power supply voltage, are thus corrected.

The present invention therefore allows using an integrated circuit for very precise measurement of a duration of a level of an electrical signal. When implemented as a microelectronic circuit, the present invention can be used in embedded systems, such as mobile phones for example.

In some embodiments of the invention, the electrical signal is a periodic electrical signal and the counts are conducted during a period of the periodic electrical signal. The number of transitions can thus be obtained by the difference between two successive counts spaced apart by a regular period. It is not necessary to synchronize the counts with the rising edges of the signal to be measured.

In some embodiments of the invention, the frequency of the first ring oscillator is at a first frequency when the electrical signal is at a first level and at a second frequency when the electrical signal is at a second level. The number of transitions between the two counts is thus a linear function of the duration of the level of the electrical signal.

In some embodiments of the invention, the first and second frequencies are non-zero. Thus, the oscillators are never reset and they retain the previous counts. The quantization errors from each count are accumulated from period to period, and the accuracy of the measurement improves from cycle to cycle. This allows shaping the quantization noise with an attenuation of its low-frequency components.

In some embodiments of the invention, the device further comprises a latch comparator at each gate of the first and second oscillators. It is thus possible to extract and store the state of all the logic levels of the oscillator at a given time and to locate the point of instability.

In some embodiments of the invention, the first counting unit comprises two counters and the second counting unit comprises two counters, wherein the device further comprises a selection unit configured to select, for each of the first and second ring oscillator, one of the two counters of each of the first counting unit and the second counting unit on a basis of a position of the point of instability in the ring oscillator. It is thus possible to use ring oscillators having a shorter period than that of the signal to be measured. Additional periods are stored by the loop counters. The total number of transitions is obtained by combining the number of loops completed and the position of the point of instability in the current loop at the moment of observation.

In some embodiments of the invention, the inverting gates are differential logic gates. The detection of logic levels in the oscillator is thus more reliable. The fact that the inverting gates are differential allows eliminating the common mode errors inherent in asymmetric structures. These errors are related in particular to noise in the power supply and to variations in the stage to stage baseline comparison levels.

In some embodiments of the invention, the propagation delay of the inverting gates of the first ring oscillator is different from the propagation delay of the inverting gates of the second ring oscillator. It is then possible to reduce the size of the device of the invention when it is implemented as an integrated circuit, simplifying the implementation of the invention.

The invention also relates to a phase-locked loop comprising a device for measuring a duration of a level of an electrical signal according to the invention. The invention thus allows measuring the duration of the signal level which, in the case of a phase-locked loop, contains the phase difference information for the system. The present invention enables a reliable and accurate digital/analog conversion. The insensitivity to noise in the power supply allows the implementation of high performance locked loops when there is phase noise.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of the specification, illustrate embodiments of the invention and together with the description serve to explain the principles of the invention. In the drawings:

FIG. 1 is a digital phase-locked loop possibly used in embodiments of the invention;

FIG. 2 is a module for measuring the duration of a pulse using two ring oscillators according to embodiments of the present invention;

FIG. 3 is an example of a ring oscillator and its associated decoder possibly used in embodiments of the invention;

FIG. 4 is an example of variations in the decoders associated with the two ring oscillators according to embodiments of the present invention.

Same reference indicators that are shown in different ones of these figures denote identical elements of elements with identical function. In addition, components with well-known functions and operation but not connected directly to the invention features are not described in detail.

### DETAILED DESCRIPTION OF THE PREFERRED EMBODIMENTS

Reference will now be made in detail to embodiments, examples of which are illustrated in the accompanying drawings. In the following detailed description, numerous non-limiting specific details are set forth in order to assist in understanding the subject matter presented herein. It will be apparent, however, to one of ordinary skill in the art that various alternatives may be used without departing from the scope of the present invention and the subject matter may be practiced without these specific details.

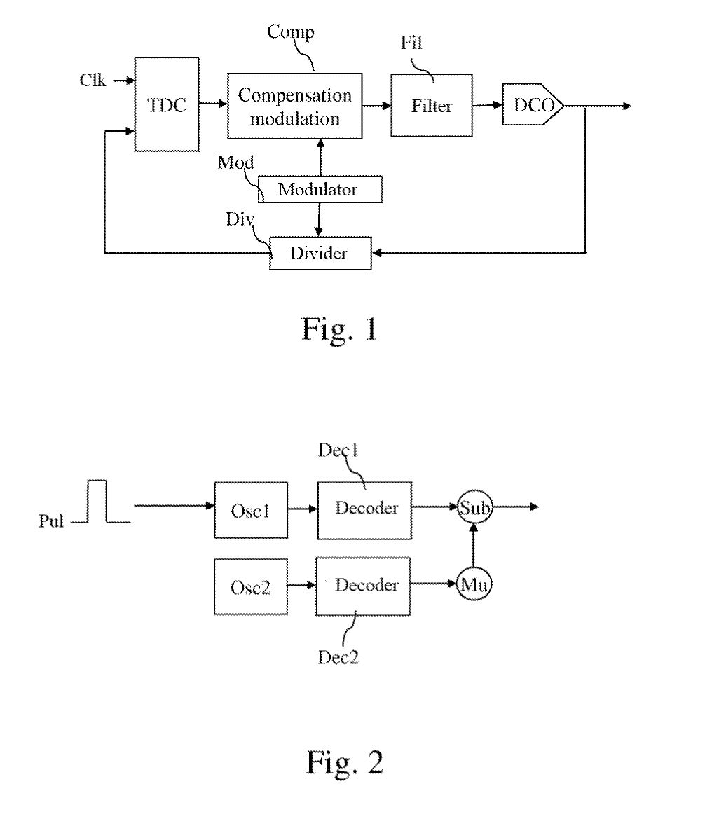

FIG. 1 is a digital phase-locked loop possibly used in embodiments of the invention. A phase-locked loop such as shown in FIG. 1 allows linking the instantaneous phase of an output signal to the instantaneous phase of a signal of fixed frequency. A phase-locked loop also allows synthesizing a clock of programmable frequency based on the fixed-frequency signal Clk. A digital phase-locked loop possibly used in the present invention comprises a time-to-digital converter TDC, a digital loop filter Fil, a digitally-controlled oscillator DCO, and a divider Div. Optionally, the digital phase-locked loop may also comprise a modulation compensation module Comp and a modulator Mod.

The modulator Mod may be, for example, a Sigma-Delta modulator and have the function of modulating the value of the division ratio from cycle to cycle in order to obtain a non-integer ratio between the frequency of the digitally-controlled oscillator DCO and that of the reference signal. The modulation compensation module Comp may be, for example, a Sigma-Delta modulation compensation module.

The reference clock Clk is compared by the time-to-digital converter TDC to the output signal from the digitally-controlled oscillator DCO divided by the divider Div. At each cycle of the reference clock, the phase difference between the reference clock Clk and the divided output signal from the digitally-controlled oscillator DCO is converted into a corresponding pulse shown as Pul in FIG. 2.

The time-to-digital converter TDC comprises a module for measuring the duration of a pulse using two ring oscillators. The module for measuring the duration of a high level pulse using two ring oscillators measures the duration of this pulse. The module for measuring the duration of a pulse will be further described below with reference to FIG. 2.

The duration of the high level of the signal Pul is supplied to a modulation compensation module Comp. The modulation compensation module Comp compensates cycle by cycle for phase errors generated by the switching that degrade the spectral purity of the signal. These errors are easily dealt with by the modulation compensation module Comp, which digitally processes the signal.

The signal that is output by the modulation compensation module Comp is then filtered by a digital filter Fil. The filter Fil is used to stabilize the phase-locked loop and adjust the dynamic parameters of the phase-locked loop to the application where the phase-locked loop is employed. The dynamic parameters of the phase-locked loop are, for example, the bandwidth and damping factor. These parameters are important factors in the phase noise performance of the phase-locked loop.

The filter Fil also eliminates some of the energy of the fractional modulation. The output from the filter Fil controls the digitally-controlled oscillator DCO, which provides a phase-locked signal. The phase-locked signal is divided by the divider Div connected to the time-to-digital converter TDC.

FIG. 2 is a module for measuring the duration of a pulse using two ring oscillators according to embodiments of the invention.

A ring oscillator is composed of an odd number of inverting gates, also known as inverters or NOT gates, whose outputs oscillate between two voltage levels. The gates are connected in a chain and the output from the last gate in the chain is connected to the input to the first gate in the chain. The frequency supplied by a ring oscillator depends on the number of inverting gates and on the gate propagation delay.

According to some embodiments of the present invention, the module for measuring the duration of a pulse comprises a first ring oscillator Osc1, which outputs a first measurement of the duration of the pulse Pul. The signal Pul modulates the nominal power supply voltage of the ring oscillator Osc1.

For example and without limitation, the nominal voltage is 1.2 volts. When the signal Pul is high, the supply voltage of the ring oscillator Osc1 is equal to 95% of the nominal voltage, which is on the order of 1.15 Volts, and when the signal Pul is low, the supply voltage of the ring oscillator Osc1 is non-zero, for example equal to 70% of the nominal voltage, which is on the order of 0.85 Volts.

A ring oscillator is very sensitive to variations in its supply voltage. Accordingly, the output frequency of the ring oscillator Osc1 is thus modified depending on whether the signal Pul is high or low.

A ring oscillator has a point of instability. The point of instability of a ring oscillator is located at the inverting gate where the input logic level is the same as the output logic level. The point of instability moves from gate to gate in the ring oscillator.

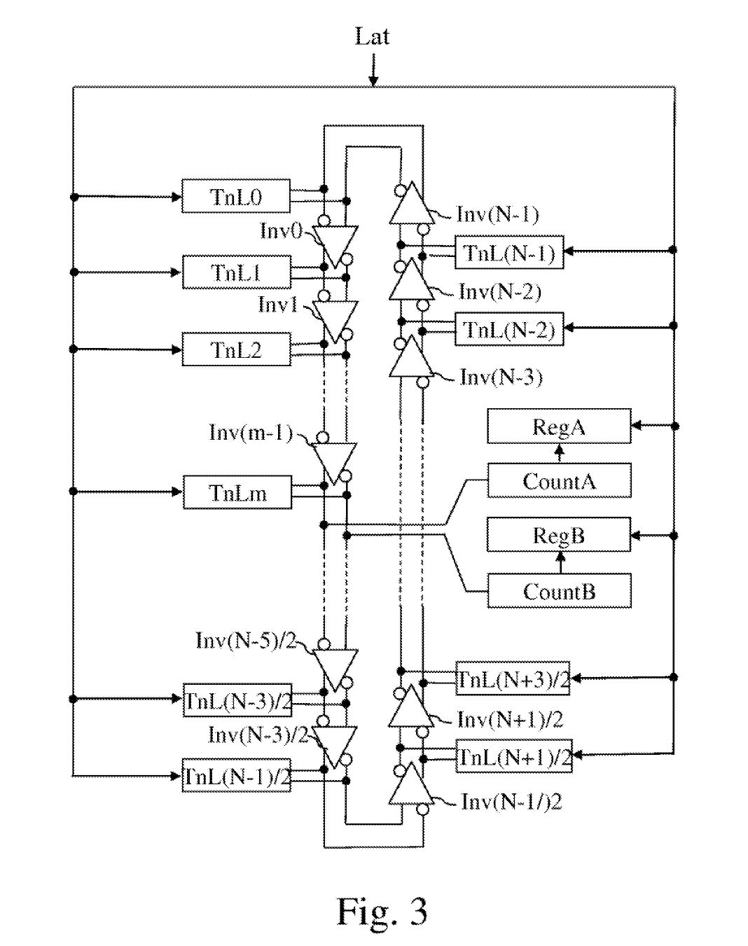

The number of loops completed by the point of instability in the ring oscillator Osc1 during the high and low levels of the signal Pul is counted by the counters CountA and CountB (FIG. 3). The position of the point of instability in the current loop is stored by latch comparators. The decoder Dec1 combines these two pieces of information to provide the total number of transitions since the previous sampling time in order to increase the accuracy of the measurement of the pulse duration.

According to some embodiments of the present invention, the module for measuring the duration of a pulse comprises a second ring oscillator Osc2, which oscillates independently of the pulse Pul. The supply voltage of the second ring oscillator Osc2 is not modulated by the signal Pul and corresponds to the nominal supply voltage, which is for example on the order of 1.2 Volts.

The number of loops traveled by the point of instability in the ring oscillator Osc2 during the high and low levels of the signal Pul is counted by counters similar to CountA and CountB (FIG. 3). The position of the point of instability within the current loop is stored by the latch comparators. The decoder Dec2 combines these two pieces of information to provide the total number of transitions since the previous sampling time.

When the nominal supply voltage varies, a variation related to the switching noise of electronic components, for example, changes the frequency of the ring oscillator Osc1 and causes an error in the measurement of the pulse Pul. Moreover, when the nominal supply voltage varies, the propagation delays of the inverting gates of the two ring oscillators Osc1 and Osc2 vary proportionally to the square of the variation of the supply voltage.

Using the second ring oscillator according to embodiments of the present invention, it is then possible to compensate for the error in the measurement of the high level of the signal Pul related to possible variations in the nominal supply voltage.

It should be noted here that the number of inverting gates contained in ring oscillator Osc2 is the same as or is different from the number of inverting gates contained in ring oscillator Osc1. To achieve a more compact module for measuring the duration of a pulse, the number of inverting gates contained in ring oscillator Osc2 is less than the number of inverting gates contained in ring oscillator Osc1.

When the propagation delay of the inverting gates contained in ring oscillator Osc2 is different from the propagation delay of the inverting gates contained in ring oscillator Osc1, the module for measuring the duration of a pulse may comprise a multiplier Mu, which multiplies the information delivered by the decoder Dec2 by a multiplication coefficient determined by the relationship between the propagation delay of the inverting gates contained in ring oscillator Osc2 and the propagation delay of the inverting gates contained in ring oscillator Osc1.

When the electrical structures of the inverting gates of oscillators Osc1 and Osc2 are different, as the propagation delay of an inverting gate is a function of its structure, the propagation delays of the inverting gates of oscillators Osc1 and Osc2 are different.

The pieces of information provided by decoders Dec1 and Dec2 are then subtracted to compensate for any variations in the nominal supply voltage. The subtraction establishes the set-point for the system. The loop filter Fil is basically an integrator, and the stable state of the phase-locked loop is achieved only when its input, the result of the subtraction, averages zero.

The duration of a level of a measured electrical signal is such that the number of transitions of oscillator Osc1 equals the number of transitions of oscillator Osc2 multiplied by the coefficient Mu.

FIG. 3 is an example of a ring oscillator and its associated decoder possibly used in embodiments of the present invention having a ring oscillator Osc1 and decoder Dec1.

For simplicity, the device for modulating the supply voltage of ring oscillator Osc1 is not represented in FIG. 3. But, it should be noted that ring oscillator Osc2 and decoder Dec2 have the same structure as is described in FIG. 3 for Osc1 and Dec1.

The ring oscillator Osc1 is composed of N inverting gates Inv0 to Inv(N−1). For simplicity, only inverting gates Inv0, Inv1, Inv(m−1), Inv(N−5)/2, Inv(N−3)/2, Inv(N−1)/2, Inv(N+1)/2, Inv(N−3), Inv(N−2), and Inv(N−1) are shown.

The inverting gates Inv0 to Inv(N−1) may be differential logic gates, which allow obtaining more accurate measurements.

Latch comparators TnL0 to TnL(N−1) are placed at the input to each inverting gate Inv0 to Inv(N−1).

For simplicity, only latch comparators TnL0, TnL1, TnL2, TnL(m), TnL(N−3)/2, TnL(N−1)/2, TnL(N+1)/2, TnL(N+3)/2, TnL(N−2), and TnL(N−1) are shown. Latch comparators TnL0 to TnL(N−1) store the logic states at the input of each inverting gate Inv0 to Inv(N−1) on the rising edge of the latch signal Lat. The output from these comparators is decoded to determine the position of the instability within the loop by a decoder which is not shown in FIG. 3.

A first counter CountA is placed on a first output of an inverting gate, for example, inverting gate Inv(m−1) on the positive output from the differential logic gate Inv(m−1).

A second counter CountB is placed on the second output of the same inverting gate Inv(m−1). For example, the first counter CountA is placed on the negative output of the differential logic gate Inv(m−1).

Counters CountA and CountB count the loops completed by the point of instability.

A register RegA, triggered by the latch signal Lat, is connected to counter CountA. The latch signal Lat triggers a sample once per cycle of the reference clock of the phase-locked loop.

A register RegB, triggered by the latch signal Lat, is connected to counter CountB.

According to an embodiment of the present invention, the value of counter CountA or CountB is selected based on the position of the point of instability in ring oscillator Osc1.

The output registers of the counters store the content on the rising edge of the latch signal. In some cases, a counter may be in the process of changing state at the moment of the rising edge of the sampling signal, producing corrupted data. If the register data are unusable as a result, the data from the second counter must be valid because it is opposite the instability in the ring since the input or output signals of the differential logic gates are in phase opposition, while the two counters CountA and CountB operate on the rising edge.

Accordingly, decoding the position of the instability thus allows determining which of the counters CountA and CountB contains unquestionably valid data.

The latch signal Lat is a periodic signal and periodically samples the input state of inverting gates Inv0 to Inv(N−1). The value of counters CountA or CountB at the ith sample is denoted by C[i] and the position of the instability in the ring is denoted by p[i].

For each of the ring oscillators Osc1, Osc2, the total number of stage-to-stage transitions of the point of instability A[i] at sample i is given by:

Λ[i]=N*C[i]+p[i].

Between each sample, the total number of gate-to-gate transitions of the point of instability is equal to:

ΔΛ[i]=Λ[i]−Λ[i−1].

When ΔΛ[i] has a negative value, it corresponds to having exceeded the maximum value that counters CountA and/or CountB can assume. A correction to the values of counters CountA and/or CountB is then made.

The duration of the high state Δt of the signal Pul is measured using ring oscillator Osc1. The frequency supplied by oscillator Osc1 is equal to Fₘₐₓ when the signal Pul is high and is equal to Fₘᵢₙ when the signal Pul is low.

Between two successive samplings, which is a time interval of duration Tₑ, the number of transitions in ring oscillator Osc1 is obtained by:

ΔΛ_{osc1}[i]=Δt*N*(Fₘₐₓ−Fₘᵢₙ)+Te*N*Fₘᵢₙ.

Between two successive samplings, which is a time interval of duration Te, the number of transitions in ring oscillator Osc2 is obtained by:

ΔΛ_{osc2}[i]=Te*M*F_{osc2}

where M is the number of inverting gates of oscillator Osc2 and F_{osc2} is the frequency of oscillator Osc2.

By taking the difference ΔΦ[i] between the number of transitions in ring oscillator Osc1 and oscillator Osc2, one obtains:

ΔΦ[i]=Δt*N*(Fₘₐₓ−Fₘᵢₙ)+Te*N*Fₘᵢₙ−Te*M*F_{osc2}.

If the duration Δt₀ for which ΔΦ[i] is zero is calculated, one obtains:

Δt₀=Te*(N*Fₘᵢₙ−M*F_{osc2})/(N*(Fₘₐₓ−Fₘᵢₙ)).

This value Δt₀ is the duration of the pulse which produces a zero value at the input to the filter Fil and corresponds to the rest point of the system, that is to say a constant phase difference at the input to the time-to-digital converter TDC.

As the frequencies Fmax, Fmin, and F_{osc2} of the oscillators are disrupted to the same extent by the variations in the supplied power, this amount is independent of said variations.

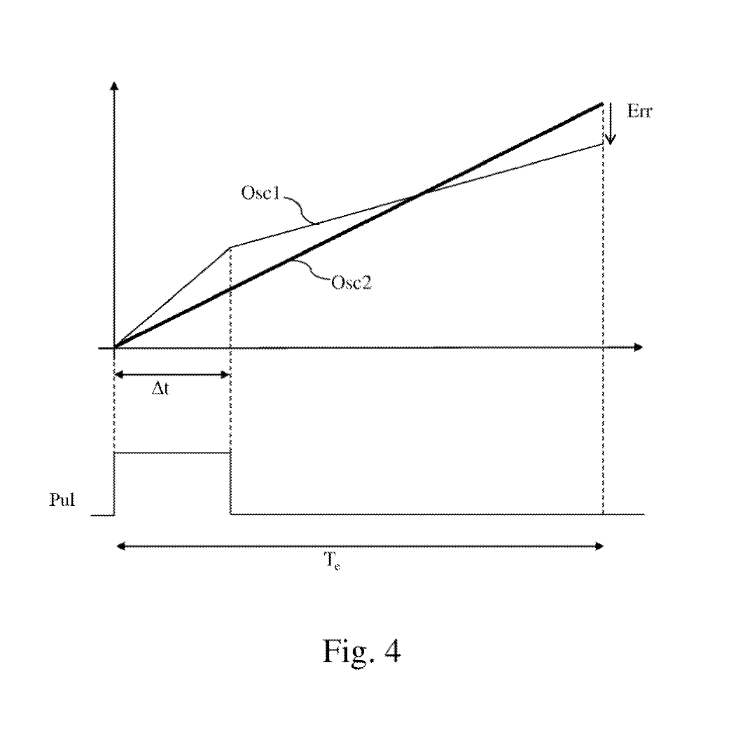

FIG. 4 shows exemplary variations of the decoders associated with the two ring oscillators according to an embodiment of the present invention. FIG. 4 illustrates the signal Pul, and the variations of the counters of oscillators Osc1 and Osc2 between two samples. The time is represented on the horizontal axis.

For the duration of the high state Δt of the signal Pul, the frequency delivered by oscillator Osc1 is equal to Fₘₐₓ. Between two successive samplings, which is during the time interval Tₑ, the number of transitions in ring oscillator Osc1 is obtained by:

ΔΛ_{osc1}[i]=Δt*N*(Fₘₐₓ−Fₘᵢₙ)+Te*N*Fₘᵢₙ.

Between two successive samplings, which is during the time interval Tₑ, the number of transitions in ring oscillator Osc2 is obtained by:

ΔΛ_{osc2}[i]=Te*M*F_{osc2}.

By taking the difference ΔΦ[i], denoted Err in FIG. 4, between the number of transitions in ring oscillator Osc1 and oscillator Osc2, one obtains:

ΔΦ[i]=Δt*N*(Fₘₐₓ−Fₘᵢₙ)+Te*N*Fₘᵢₙ−Te*M*F_{osc2}.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

1. A device for measuring a duration of a level of an electrical signal, comprising:
a first ring oscillator comprising inverting gates and supplied by an electrical power supply modulated by the electrical signal;
a second ring oscillator supplied by an electrical power supply not modulated by the electrical signal;
a first counting unit configured to count a total number of gate-to-gate transitions of a point of instability of the first ring oscillator, a point of instability being present at an inverting gate when a logic level at an input to the inverting gate is equal to a logic level at an output from the inverting gate;
a second counting unit configured to count a total number of gate-to-gate transitions of a point of instability of the second ring oscillator; and
a determining unit configured to duration of a level of the electrical signal on a basis of values of the first and second counting units.

2. The device according to claim 1, wherein the electrical signal is a periodic electrical signal and wherein the counts are conducted during a period of the periodic electrical signal.

3. The device according to claim 1, wherein a frequency of the first ring oscillator is at a first frequency when the electrical signal is at a first level and at a second frequency when the electrical signal is at a second level.

4. The device according to claim 3, wherein the first and second frequencies are non-zero.

5. The device according to claim 1, further comprising a latch comparator at each gate of the first and second oscillators.

6. The device according to claim 1, wherein the first counting unit comprises two counters and the second counting unit comprises two counters, wherein
the device further comprises a selection unit configured to select, for each of the first and second ring oscillator, one of the two counters of each of the first counting unit and the second counting unit on a basis of a position of the point of instability in the ring oscillator.

7. The device according to claim 1, wherein the inverting gates are differential logic gates.

8. The device according to claim 1, wherein a propagation delay of the inverting gates of the first ring oscillator is different from a propagation delay of the inverting gates of the second ring oscillator.

9. A phase-locked loop comprising a device for measuring a duration of a level of an electrical signal according to claim 1.
